(19) United States
(12) Patent Application Publication
(10) Pub. No.: US 2025/0393203 A1
(43) Pub. Date: Dec. 25, 2025

(54) METHOD OF MAKING NAND FLASH MEMORY

(71) Applicant: Shanghai Huali Microelectronics Corporation, Shanghai (CN)

(72) Inventors: Yishan WU, Shanghai (CN); Shaokang YAO, Shanghai (CN)

(21) Appl. No.: 18/885,259

(22) Filed: Sep. 13, 2024

(30) Foreign Application Priority Data
Jun. 21, 2024 (CN) 202410814681.9

(51) Int. Cl. H10B 41/35; H10B 41/10

(52) U.S. Cl. CPC H10B 41/35; H10B 41/10

(57) ABSTRACT

The application discloses a method of making a NAND flash memory, comprising: step 1. providing a semiconductor substrate in which the production of a gate structure is completed, step 2. forming a first spacer on a second side of a second gate structure of a selection transistor and a first filling layer in a spacing region within a block, step 3. forming a second filling layer to fill a peripheral spacing region, step 4. removing the first filling layer in the spacing region within a block and forming a first gap, while removing the first spacer of the peripheral spacing region and part of the second filling layer and forming a second gap, step 5. performing growth of a first dielectric layer to seal the first gap, and step 6. performing growth of the second dielectric layer to completely fill the residue gap in the second gap.

### CROSS-REFERENCES TO RELATED APPLICATIONS

This application claims priority to Chinese patent application No. 202410814681.9, filed on Jun. 21, 2024, the disclosure of which is incorporated herein by reference in its entirety.

### TECHNICAL FIELD

The present application relates to the field of semiconductor integrated circuits, and in particular to a method of making a NAND flash memory.

### BACKGROUND

NAND flash, as an important flash memory device, achieves a relatively high storage density due to its structure with a very high unit density, and very-fast writing and erasing speeds. Thus, the NAND flash is widely used in various memory cards, and is gradually replacing solid state drives of mechanical hard disks.

With decrease in a device size, a NAND device has a block region in which a size of a spacing between word lines also decreases to cause serious inter-cell coupling interference problems for a floating gate memory, thereby affecting a cell threshold voltage, and programming and reading speeds of a memory array. To solve this problem, a process involving the airgap isolation technology is introduced for producing NAND flash, aiming to improve a capacitive coupling effect between floating gates of word lines of a device by introducing air, a material with the lowest dielectric constant, between floating gates.

In the existing method for forming an air gap for NAND flash, it is usually necessary to ensure to fill a second gap formed in a region between storage blocks when a first gap between gates of a memory cell is opened for sealing thereof. Herein, the width of the second gap is usually greater than that of the first gap. To ensure that the second gap is filled, the volume of the air gap formed after the first gap is sealed would be reduced. However, if the air gap formed after sealing the first gap needs to be expanded, and the dielectric growth process for sealing the first gap cannot ensure that the second gap is filled, a residual gap would be produced in the second gap. The residual gap may cause a bridge for contact holes in the same row formed between storage blocks, that is, a CT bridge defect.

Referring to FIG. 1A, it is an image of a cross section of a device formed by an existing method of making a NAND flash memory. FIG. 1B is an image of a top view of a device formed by an existing method of making a NAND flash memory. An air gap 102 is formed between first gate structures 101a of a storage cell. A selection transistor is located at an edge of a storage block, and two corresponding contact holes 103 are formed between second gate structures 101b of selection transistors of two adjacent storage blocks. However, metal in the contact hole 103 overflows into the residue gap of the second gap outside the opening of the contact hole 103, and the overflown metal is separately indicated by the reference number 103a. Referring to FIG. 1B, the overflown metal corresponding to the reference number 103a causes a short circuit for the contact holes 103 in the same row.

### BRIEF SUMMARY

According to some embodiments in this application, a method of making a NAND flash memory provided by the application comprises steps of:
step 1. providing a semiconductor substrate in which the production of a gate structure is completed, wherein the gate structure comprises a first gate structure of a storage cell and a second gate structure of a selection transistor; and
a plurality of the storage cells form a storage block in which both sides of the storage cell in each column are provided with a selection transistor;
step 2. performing a spacer process to form a first spacer on a second side of the second gate structure and form a first filling layer composed of a material layer of the first spacer, wherein the first filling layer fills spacing regions within a block between a first side of the second gate structure and a side of an adjacent first gate structure, and between sides of the first gate structure;
step 3. forming a second filling layer to fill a peripheral spacing region outside the storage block;
step 4. performing a first etching process to remove the first filling layer in the spacing region within the block and form a first gap, wherein the first etching process simultaneously forms a second gap in the peripheral spacing region, the second gap is formed by removing the first spacer and part of the second filling layer, the width of the second gap is greater than the width of the first gap, the first gap has a first depth-to-width ratio, the second gap has a second depth-to-width ratio, and the first depth-to-width ratio is greater than the second depth-to-width ratio;
step 5. performing growth of a first dielectric layer to seal the first gap, and stopping the growth of the first dielectric layer before the second gap is sealed;
wherein an air gap is composed of the first gap sealed by the first dielectric layer; and
the growth process for the first dielectric layer has a first filling capability which can enable filling of a gap with a depth ratio which is a third depth-to-width ratio less than the second depth-to-width ratio, the air gap is enlarged by reducing the first filling ability, and the worse the first filling ability is, the smaller the third depth-to-width ratio is, and the larger the air gap is, and
step 6. performing growth of a second dielectric layer, wherein the growth process for the second dielectric layer has second filling ability greater than the first filling ability and sufficient to enable filling of a residue gap in the second gap.

In some examples, the method further comprises:
step 7. forming an interlayer film on a top surface of the second dielectric layer; and
step 8. forming a contact hole opening and filling metal in the contact hole opening to form a contact hole;
wherein the contact hole comprises a first contact hole outside the second side of the second gate structure, the first contact hole passes through the interlayer film, the second dielectric layer, the first dielectric layer, and the second filling layer, and the structure in which the second gap is filled prevents the metal in the first contact hole from extending into the second gap and thereby prevents a short circuit for the first contact holes in the same row.

In some examples, in step 6, the raw material of the second dielectric layer has fluidity with which the residue gap in the second gap is filled; and
the second dielectric layer is formed after the raw material of the second dielectric layer is cured.

In some examples, in step 6, the raw material of the second dielectric layer comprises polysilazane (PSZ).

In some examples, in step 5, the first dielectric layer is formed by a CVD process.

In some examples, the material of the first dielectric layer comprises silicon oxide.

In some examples, the spacer process of step 2 comprises the following sub-steps:
step 21. forming the material layer of the first spacer, wherein the material layer of the first spacer ensures that the spacing region within the block is filled and the peripheral spacing region is not fully filled, and the material layer of the first spacer also extends to the top surface of the first gate structure and the top surface of the second gate structure; and
step 22, etching the material layer of the first spacer to form the first spacer and the first filling layer, wherein the material layer of the first spacer is removed, which is on the top surface of the first gate structure and the top surface of the second gate structure, and on the bottom surface of the peripheral spacing region outside the first spacer.

In some examples, the material layer of the first spacer comprises a third oxide layer and a fourth nitride layer successively stacked.

In some examples, in step 3, the second filling layer comprises a fifth oxide layer.

In some examples, the second filling layer further comprises a sixth nitride layer, on the top surface of which the fifth oxide layer is stacked.

In some examples, the second filling layer also comprises a seventh oxide layer, on the top surface of which the sixth nitride layer is stacked.

In some examples, the third oxide layer is formed by an ALD process and the seventh oxide layer is formed by the ALD process.

In some examples, the first etching process is nitride layer etching, the exposed fourth nitride layer is completely removed and the sixth nitride layer is partially removed.

In some examples, the top surface of the first gate structure is flush with the top surface of the second gate structure, a first etch back process is also comprised before the first etching process, the first etch back process realizes etching of both the nitride layer and the oxide layer, and the first etch back process enables the top surfaces of the first fill layer, the first spacer, and the second fill layer below the top surface of the top surface of the first gate structure, thereby exposing a top segment of the first gate structure and a top segment of the second gate structure.

In some examples, the first gate structure comprises a first gate dielectric layer, a floating gate, an inter-gate dielectric layer, and a control gate successively stacked; and
the second gate structure comprises a second gate dielectric layer and a selection gate successively stacked.

In some examples, the floating gate is formed by a first polysilicon layer in a floating gate formation region;
the control gate is formed by a second polysilicon layer in a control gate formation region; and
the selection gate is formed by stacking a first polysilicon layer and a second polysilicon layer in a selection gate formation region.

In some examples, the top segment of the first gate structure and the top segment of the second gate structure exposed after the first etch back process are the top segment of the control gate, and the top segment of the second polysilicon layer of the selection gate, respectively; and
after the first etching process in step 4 is completed, and before the growth of the first dielectric layer in step 5, the method also comprises:
forming metal silicide.

In the application, growth of a sealing dielectric layer for an air gap between gates for a storage cell is specially set after removing a filling material between gates by etching, i.e., after a first etching process is completed; and a first dielectric layer is formed by a growth process with poor filling ability, and a first gap is quickly sealed by means of first, relatively poor, filling ability of the first dielectric layer, so that a size of an air gap can be increased. Thus, the application can enable a sufficiently large air gap formed between gates of a storage cell.

Also, due to the relatively poor first filling ability, it is easy to seal the second gap by the first dielectric layer. In the application, growth of the first dielectric layer is stopped before the first dielectric layer seals the second gap, and then the second dielectric layer is formed by a growth process with second filling ability. The second filling ability is greater than the first filling ability and the second dielectric layer ensures that the residue gap in the second gap is filled. So, the application can avoid formation of voids in a peripheral spacing region.

Contact holes are usually formed in a peripheral spacing region and used for leading out of active regions such as a source or drain region at the bottom. The application can avoid a bridge for contact holes in the same row in the peripheral spacing region. For example, a corresponding first contact hole, which is formed in the peripheral spacing region outside the second side of the second gate structure, has a bottom that would contact with an active region, such as a source or drain region, outside the second side of the selection transistor. The application eliminates the voids in the peripheral spacing region, and thus, can prevent a short circuit for adjacent first contact holes in the same row.

### BRIEF DESCRIPTION OF THE DRAWINGS

The present application is described in further detail below in connection with figures and specific embodiments:

FIG. 1A is an image of a cross section of a device formed by an existing method of making a NAND flash memory;

FIG. 1B is an image of a top view of a device formed by an existing method of making a NAND flash memory;

FIG. 2 is a flow chart of the method of making a NAND flash memory according to an embodiment of the application;

FIG. 3 is a schematic diagram of a top-view structure of a storage array of devices formed by the method of making a NAND flash memory according to an embodiment of the application;

FIG. 4 is a schematic diagram of a top-view structure of a storage block in a storage array of devices formed by the method of making a NAND flash memory according to an embodiment of the application;

FIG. 5 is a circuit diagram formed by a row of memory cells in FIG. 4; and

FIG. 6A-FIG. 6J are schematic diagrams of cross section structures of a device in each step of the method of making a NAND flash memory according to an embodiment of the application.

### DETAILED DESCRIPTION OF THE DISCLOSURE

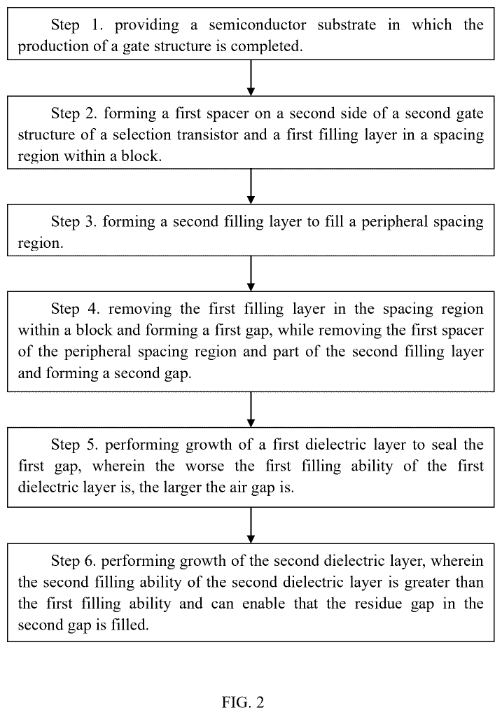

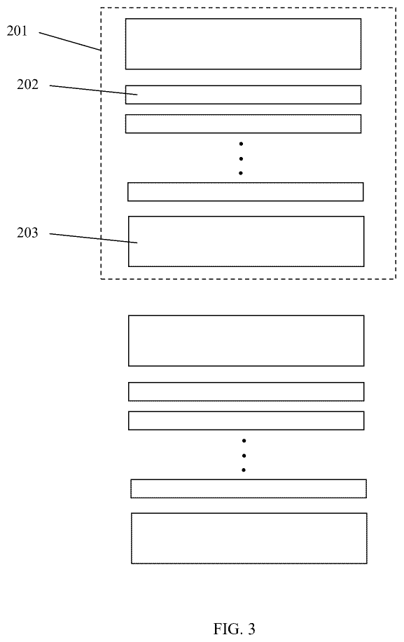

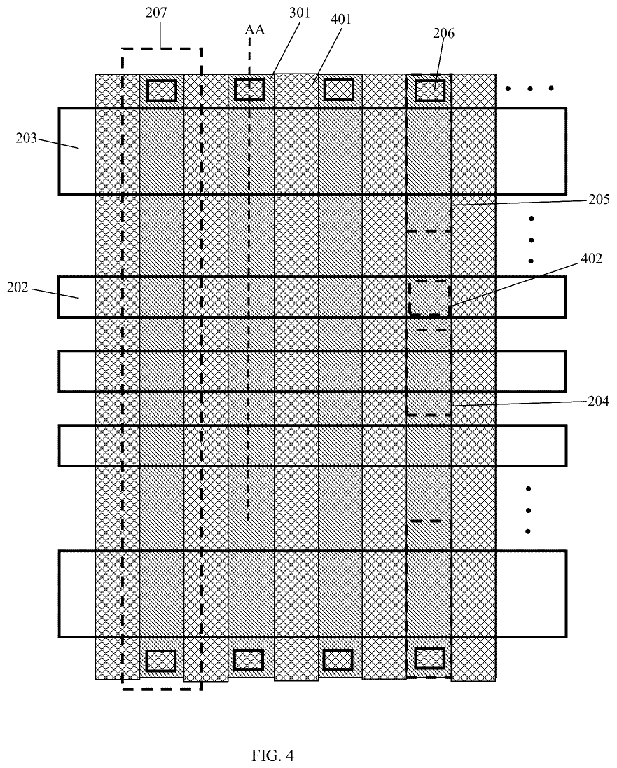

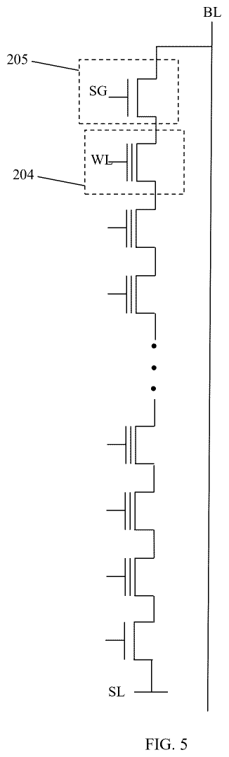

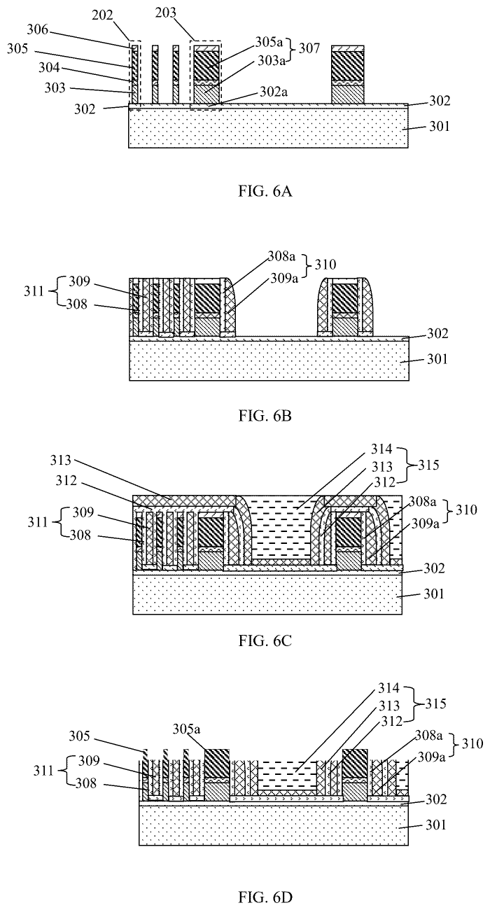

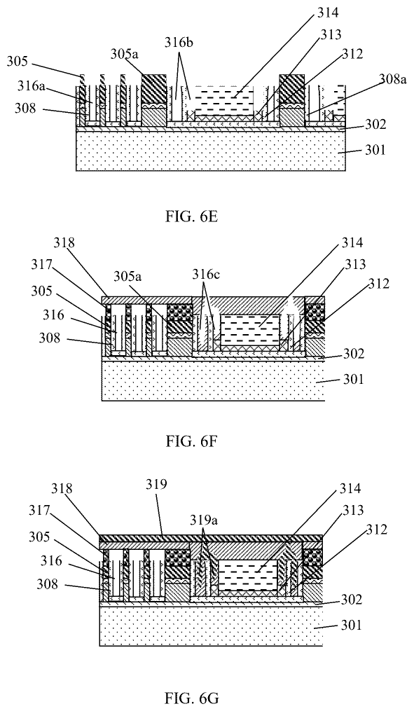

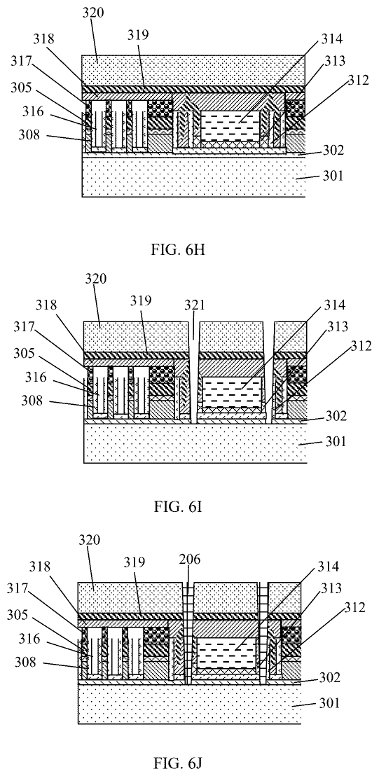

Referring to FIG. 2, it is a flow chart of a method of making a NAND flash memory according to an embodiment of the application; FIG. 3 a schematic diagram of a top-view structure of a storage array of devices formed by the method of making a NAND flash memory according to an embodiment of the application; FIG. 4 is a schematic diagram of a top-view structure of a storage block 201 in a storage array of devices formed by the method of making a NAND flash memory according to an embodiment of the application; FIG. 5 is a circuit diagram formed by a row of memory cells 204 in FIG. 4; and FIG. 6A-FIG. 6J are schematic diagrams of cross section structures of a device in each step of the method of making a NAND flash memory according to an embodiment of the application; and the method of making a NAND flash memory according to an embodiment of the application comprises:
step 1. referring to FIG. 6A, providing a semiconductor substrate in which the production of a gate structure is completed, wherein the gate structure comprises a first gate structure 202 of a storage cell 204 and a second gate structure 203 of a selection transistor 205.

Referring to FIG. 3, the storage array comprises a plurality of storage blocks 201. FIG. 3 only shows a parallel-arrangement structure of the first gate structure 202 and the second gate structure 203, and two storage blocks 201. It can be seen that the second gate structure 203 corresponding to two selection transistors 205 is located at edges of both sides of the storage block 201. There are spacings between the storage blocks 201, and between adjacent second gate structures 203 between the storage blocks 201, and the spacing between adjacent second gate structures 203 is greater than the spacing between the first gate structures 202. In general, the spacing between the second gate structure 203 and an adjacent first gate structure 202 is equal to the spacing between the first gate structures 202. The width of the second gate structure 203 is greater than that of the first gate structure 202.

Referring to FIG. 4, a plurality of the storage cells 204 form a storage block 201 in which both sides of the storage cell 204 in each column are provided with a selection transistor 205.

In a row direction, a plurality of field oxide layers 401 arranged in parallel are comprised, and the semiconductor substrate 301 between the field oxide layers 401 constitutes an active region.

For the storage cell 204, a channel region is formed in the active region covered by the first gate structure 202, and doped heavily source and drain regions are formed in the active regions at both sides of the first gate structure 202.

For the selection transistor 205, a channel region is formed in the active region covered by the second gate structure 203, and doped heavily source and drain regions are formed in the active regions at both sides of the second gate structure 203.

Referring to FIG. 5, it is a circuit diagram formed by a row of storage cells 204 shown by the dotted line box 207 in FIG. 4. As can be seen, a plurality of the storage cells 204 are connected in series, and one of the selection transistors 205 is connected in series to both sides of the series structure of the storage cell 204. The drain region of one selection transistor 205 would be connected to a bit line BL, and the source region of another selection transistor 205 would be connected to a source line SL. The bit line BL and source line SL are formed by a metal interconnect process in a subsequent process.

Referring to FIG. 6A, in the embodiment of the application, the first gate structure 202 comprises a first gate dielectric layer 302, a floating gate 303, an inter-gate dielectric layer 304, and a control gate 305 successively stacked.

The second gate structure 203 comprises a second gate dielectric layer 302a, and a selection gate 307 successively stacked.

The floating gate 303 is formed by a first polysilicon layer in a floating gate formation region. In FIG. 4, the floating gate formation region, as shown by the dotted line box 402, is the region where the second gate structure 303 intersects the active region.

The control gate 305 is formed by a second polysilicon layer in a control gate formation region.

Generally, to facilitate production, the selection gate 307 is formed by stacking a first polysilicon layer 303a and a second polysilicon layer 305a in the selection gate formation region; the second gate dielectric layer 302a is also composed of the first gate dielectric layer 302; and furthermore, an inter-gate dielectric layer 304 is also stacked between the first polysilicon layer 303a and the second polysilicon layer 305a, however, the inter-gate dielectric layer 304 in some regions of the selection gate formation region is removed, so that, the first polysilicon layer 303a and the second polysilicon layer 305a are in contact and referred as the selection gate 307 as a whole.

Referring to FIG. 4, in the first gate structure 202, the floating gate 303 is only in the region shown by the dotted line frame 402, and the control gate 305 extends to form a word line WL. The top view of the first gate structure 202 shown in FIG. 4 is the top view of the control gate row. FIG. 5 shows that the control gate 305 of the storage cell 204 is connected to the word line WL.

Similarly, in FIG. 4, the selection gate 307 extends to form a selection gate line SG. FIG. 5 shows that the selection gate 307 is connected to the selection gate line SG.

The method comprises step 2 of, referring to FIG. 6B, performing a spacer process to form a first spacer 310 at the second side of the second gate structure 203 and form a first filling layer 311 consisting of the material layer of the first spacer 310. The first filling layer 311 fills spacing regions within a block between the first side of the second gate structure 203 and the side of the adjacent first gate structure 202, and between the sides of each first gate structure 202.

In an embodiment of the application. The spacer process comprises the following sub-steps:
step 21 of, referring to FIG. 6B, forming the material layer of the first spacer 310. The material layer of the first spacer 310 ensures that the spacing region within the block is filled and the peripheral spacing region is not fully filled, and the material layer of the first spacer 310 also extends to the top surface of the first gate structure 202 and the top surface of the second gate structure 203.

The material layer of the first spacer 310 comprises a third oxide layer 308, and a fourth nitride layer 309 successively stacked.

In some embodiments, the third oxide layer 308 is formed by an ALD process.

Step 2 comprises step 22 of, referring to FIG. 6B, etching the material layer of the first spacer 310 to form the first spacer 310 and the first filling layer 311. The material layer of the first spacer 310 is removed, which is on the top surface of the first gate structure 202 and the top surface of the second gate structure 203, and on the bottom surface of the peripheral spacing region outside the first spacer 310.

After the etching, the third oxide layer composed of the first spacer 310 is individually represented by the reference number 308a and the fourth nitride layer is individually represented by the reference number 309a.

The method comprises step 3 of, referring to FIG. 6C, forming a second filling layer 315 to fill a peripheral spacing region outside the storage block 201.

In the embodiment of the application, the second filling layer 315 comprises a fifth oxide layer 314.

The second packed layer 315 further comprises a sixth nitride layer 313, on the top surface of which the fifth oxide layer is stacked.

The second filled layer 315 also comprises a seventh oxide layer 312, on the top surface of which the sixth nitride layer 313 is stacked.

In some embodiments, the seventh oxide layer 312 is formed by the ALD process.

The sixth nitride layer 313 is used as a stop layer for the planarization of the fifth oxide layer 314. That is, after being formed, the fifth oxide layer 314 needs for planarization, for example, planarization is performed on the fifth oxide layer 314 by a etch back process or chemical mechanical polishing process and is stopped on the surface of the fifth oxide layer 314.

In the embodiment of the application, the top surface of the first gate structure 202 is flush with the top surface of the second gate structure 203, referring to FIG. 6D. A first etch back process is also comprised before a subsequent first etching process, the first etch back process realizes etching of both the nitride layer and the oxide layer, and the first etch back process enables the top surfaces of the first fill layer 311, the first spacer 310, and the second fill layer 315 below the top surface of the top surface of the first gate structure 202, thereby exposing a top segment of the first gate structure 202 and a top segment of the second gate structure 203.

The method comprises step 4 of, referring to FIG. 6E, performing a first etching process to remove the first filling layer 311 in the spacing region within a block and form a first gap 316a. The first etching process simultaneously forms a second gap 316b in the peripheral spacing region, the second gap 316b is formed by removing the first spacer 310 and part of the second filling layer 315, the width of the second gap 316b is greater than the width of the first gap 316a, the first gap 316a has a first depth-to-width ratio, the second gap 316b has a second depth-to-width ratio, and the first depth-to-width ratio is greater than the second depth-to-width ratio.

In the embodiment of the application, the first etching process is nitride layer etching, and the exposed fourth nitride layer 309 is completely removed and the sixth nitride layer 313 is partially removed, thus forming the first gap 316a and the second gap 316b.

In the embodiment of the application, the top segment of the first gate structure 202 and the top segment of the second gate structure 203 exposed after the first etch back process are the top segment of the control gate 305, and the top segment of the second polysilicon layer 305a of the selection gate 307, respectively.

After the first etching process in step 4 is completed, and before the growth of the first dielectric layer 318 in step 5, the method also comprises:
forming metal silicide 307, referring to FIG. 6F. In FIG. 6F, it shows that the metal silicide 307 is formed in part of the thickness portion of the control gate 305 and part of the thickness portion of the second polysilicon layer 305a of the selection gate 307.

In some embodiments, the metal silicide 307 comprises nickel silicide.

The method comprises step 5 of, referring to FIG. 6F, performing growth of the first dielectric layer 318 to seal the first gap 316a, and stopping the growth of the first dielectric layer 318 before the second gap 316b is sealed. In FIG. 6F, the top of the residue gap 316c in the second gap 316b remains open, but an opening width is not less than the opening width of the second gap 316b.

An air gap 316 is formed by the first gap 316a sealed by the first dielectric layer 318.

The growth process for the first dielectric layer 318 has a first filling capability which can enable filling of a gap with a depth ratio which is a third depth-to-width ratio less than the second depth-to-width ratio, the air gap 316 is enlarged by reducing the first filling ability, and the worse the first filling ability is, the smaller the third depth-to-width ratio is, and the larger the air gap 316 is.

In the embodiment of the application, the first dielectric layer 318 is formed by a CVD process.

The material of the first dielectric layer 318 comprises silicon oxide.

Since it is not required in the embodiment of the application that the first dielectric layer 318 fills the second gap 316b, and it is only required that the second gap 316b is not sealed, the reduction of the first filling ability is not limited by the filling of the second gap 316b. Thus, the first filling ability can be reduced to a relatively low level, which facilitates to maximize the air gap 316, thereby maximizing device performance.

The method comprises step 6 of, referring to FIG. 6G, performing growth of the second dielectric layer 319. The growth process for the second dielectric layer 319 has second filling ability greater than the first filling ability and sufficient to enable filling of a residue gap 316c in the second gap 316b. The second dielectric layer filled in the residue gap 316c in the second gap 316b is also individually represented by the reference number 319a in FIG. 6G.

In the embodiment of the application, the raw material of the second dielectric layer 319 has fluidity with which the residue gap 316c in the second gap 316b is filled.

The raw material of the second dielectric layer 319 forms the second dielectric layer 319 after curing.

In some embodiments, the raw material for the second dielectric layer 319 comprises polysilazane.

The method further comprises:
step 7 of, referring to FIG. 6H, forming an interlayer film 320 on the top surface of the second dielectric layer 319; and
step 8 of, referring to FIG. 6I, forming a contact hole opening 321.

Referring to FIG. 6J, the contact hole opening 321 is filled with metal to form a contact hole 206.

The contact hole 206 comprises a first contact hole outside the second side of the second gate structure 203, and FIG. 6J only shows two contact holes 206 that are first contact holes.

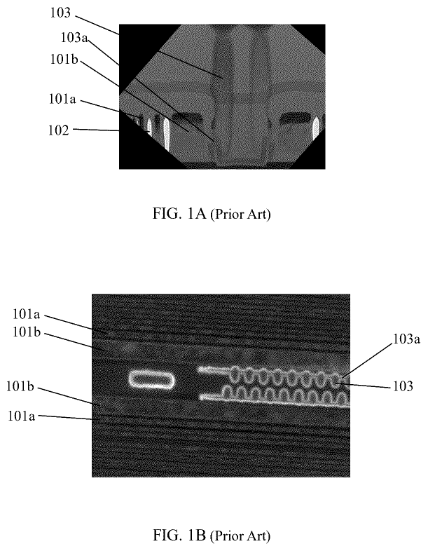

The first contact hole passes through the interlayer film 320, the second dielectric layer 319, the first dielectric layer 318, and the second filling layer 315; and the structure in which the second gap 316b is filled prevents the metal in the first contact hole from extending into the second gap 316b and thereby prevents a short circuit for the first contact holes in the same row. Returning to FIG. 4, FIG. 4 shows contact holes 206 which each is a first contact hole, and shows 2 rows of the contact holes 206 in total. The embodiment of the application can make no short circuit for the contact holes 206 in each row, thus eliminating the corresponding CT bridge defect in FIG. 1B.

In the embodiment of the application, growth of a sealing dielectric layer for an air gap 316 between gates for a storage cell 204 is specially set after removing a filling material between gates by etching, i.e., after a first etching process is completed; and a first dielectric layer 318 is formed by a growth process with poor filling ability, and a first gap 316a is quickly sealed by means of first, relatively poor, filling ability of the first dielectric layer 318, so that a size of the air gap 316 can be increased. Thus, the embodiment of the application can enable a sufficiently large air gap 316 formed between gates of a storage cell 204.

Also, due to the relatively poor first filling ability, it is easy to seal the second gap 316b by the first dielectric layer 318. In the application, the growth of the first dielectric layer 318 is stopped before the first dielectric layer 318 seals the second gap 316b, and then the second dielectric layer 319 is formed by a growth process with second filling ability. The second filling ability is greater than the first filling ability and the second dielectric layer 319 ensures that the residue gap 316c in the second gap 316b is filled. So, the application can avoid formation of voids in a peripheral spacing region.

The contact holes 206 are usually formed in a peripheral spacing region and used for leading out of active regions such as a source or drain region at the bottom. The embodiment of the application can avoid a short circuit for contact holes 206 in the same row in the peripheral spacing region. For example, a corresponding first contact hole, which is formed in the peripheral spacing region outside the second side of the second gate structure 203, has a bottom that would contact with an active region, such as a source or drain region, outside the second side of the selection transistor 205. The embodiment of the application eliminates the voids in the peripheral spacing region, and thus, can prevent a short circuit for adjacent first contact holes in the same row.

The application is described in detail above by specific embodiments without limitation to the application. Without departing from the principle of the present application, modifications and improvements may be made by those skilled in the art, which shall also be within the scope of protection of the present application.

What is claimed is:

1. A method of making a NAND flash memory, comprising steps of:
step 1. providing a semiconductor substrate in which the production of a gate structure is completed, wherein the gate structure comprises a first gate structure of a storage cell and a second gate structure of a selection transistor; and
a plurality of the storage cells form a storage block in which both sides of the storage cell in each column are provided with a selection transistor;
step 2. performing a spacer process to form a first spacer on a second side of the second gate structure and form a first filling layer composed of a material layer of the first spacer, wherein the first filling layer fills spacing regions within a block between a first side of the second gate structure and a side of an adjacent first gate structure and, between sides of the first gate structure;
step 3. forming a second filling layer to fill a peripheral spacing region outside the storage block;
step 4. performing a first etching process to remove the first filling layer in the spacing region within the block and form a first gap, wherein the first etching process simultaneously forms a second gap in the peripheral spacing region, the second gap is formed by removing the first spacer and part of the second filling layer, the width of the second gap is greater than the width of the first gap, the first gap has a first depth-to-width ratio, the second gap has a second depth-to-width ratio, and the first depth-to-width ratio is greater than the second depth-to-width ratio;
step 5. performing growth of a first dielectric layer to seal the first gap, and stopping the growth of the first dielectric layer before the second gap is sealed;
wherein an air gap is composed of the first gap sealed by the first dielectric layer; and
the growth process for the first dielectric layer has a first filling capability which can enable filling of a gap with a depth ratio which is a third depth-to-width ratio less than the second depth-to-width ratio, the air gap is enlarged by reducing the first filling ability, and the worse the first filling ability is, the smaller the third depth-to-width ratio is, and the larger the air gap is, and
step 6. performing growth of a second dielectric layer, wherein the growth process for the second dielectric layer has second filling ability greater than the first filling ability and sufficient to enable filling of a residue gap in the second gap.

2. The method of making a NAND flash memory according to claim 1, further comprising:
step 7. forming an interlayer film on a top surface of the second dielectric layer; and
step 8. forming a contact hole opening and filling metal in the contact hole opening to form a contact hole;
wherein the contact hole comprises a first contact hole outside the second side of the second gate structure, the first contact hole passes through the interlayer film, the second dielectric layer, the first dielectric layer, and the second filling layer, and the structure in which the second gap is filled prevents the metal in the first contact hole from extending into the second gap and thereby prevents a short circuit for the first contact holes in the same row.

3. The method of making a NAND flash memory according to 1, wherein in step 6, the raw material of the second dielectric layer has fluidity with which the residue gap in the second gap is filled; and
the second dielectric layer is formed after the raw material of the second dielectric layer is cured.

4. The method of making a NAND flash memory according to claim 3, wherein in step 6, the raw material of the second dielectric layer comprises polysilazane.

5. The method of making a NAND flash memory according to claim 1, wherein in step 5, the first dielectric layer is formed by a CVD process.

6. The method of making a NAND flash memory according to claim 5, wherein the material of the first dielectric layer comprises silicon oxide.

7. The method of making a NAND flash memory according to claim 1, wherein the spacer process of step 2 comprises the following sub-steps:
step 21. forming the material layer of the first spacer, wherein the material layer of the first spacer ensures that the spacing region within a block is filled and the peripheral spacing region is not fully filled, and the material layer of the first spacer also extends to the top surface of the first gate structure and the top surface of the second gate structure; and
step 22, etching the material layer of the first spacer to form the first spacer and the first filling layer, wherein the material layer of the first spacer is removed, which is on the top surface of the first gate structure and the top surface of the second gate structure, and on the bottom surface of the peripheral spacing region outside the first spacer.

8. The method of making a NAND flash memory according to claim 7, wherein the material layer of the first spacer comprises a third oxide layer and a fourth nitride layer successively stacked.

9. The method of making a NAND flash memory according to claim 8, wherein in step 3, the second filling layer comprises a fifth oxide layer.

10. The method of making a NAND flash memory according to claim 9, wherein the second filling layer further comprises a sixth nitride layer, on the top surface of which the fifth oxide layer is stacked.

11. The method of making a NAND flash memory according to claim 10, wherein the second filling layer also comprises a seventh oxide layer, on the top surface of which the sixth nitride layer is stacked.

12. The method of making a NAND flash memory according to claim 11, wherein the third oxide layer is formed by an ALD process and the seventh oxide layer is formed by the ALD process.

13. The method of making a NAND flash memory according to claim 11, wherein the first etching process is nitride layer etching, the exposed fourth nitride layer is completely removed and the sixth nitride layer is partially removed.

14. The method of making a NAND flash memory according to claim 11, wherein the top surface of the first gate structure is flush with the top surface of the second gate structure, a first etch back process is also comprised before the first etching process, the first etch back process realizes etching of both the nitride layer and the oxide layer, and the first etch back process enables the top surfaces of the first fill layer, the first spacer, and the second fill layer below the top surface of the top surface of the first gate structure, thereby exposing a top segment of the first gate structure and a top segment of the second gate structure.

15. The method of making a NAND flash memory according to claim 14, wherein the first gate structure comprises a first gate dielectric layer, a floating gate, an inter-gate dielectric layer, and a control gate successively stacked; and
the second gate structure comprises a second gate dielectric layer and a selection gate successively stacked.

16. The method of making a NAND flash memory according to claim 15, wherein:
the floating gate is formed by a first polysilicon layer in a floating gate formation region;
the control gate is formed by a second polysilicon layer in a control gate formation region; and
the selection gate is formed by stacking a first polysilicon layer and a second polysilicon layer in a selection gate formation region.

17. The method of making a NAND flash memory according to claim 16, wherein the top segment of the first gate structure and the top segment of the second gate structure exposed after the first etch back process are the top segment of the control gate, and the top segment of the second polysilicon layer of the selection gate, respectively; and
after the first etching process in step 4 is completed, and before the growth of the first dielectric layer in step 5, the method also comprises:
forming metal silicide.
